(19) United States
(12) Patent Application Publication
(10) Pub. No.: US 2008/0241708 A1
(43) Pub. Date: Oct. 2, 2008

(54) SUB-RESOLUTION ASSIST FEATURE OF A PHOTOMASK

(75) Inventors: Cheng-Ming Lin, Yunlin County (TW); Jen-Hsi Chiu, Pingtung County (TW)

Correspondence Address: HAYNES AND BOONE, LLP, 901 Main Street, Suite 3100, Dallas, TX, 75202, US

(73) Assignee: TAIWAN SEMICONDUCTOR MANUFACTURING COMPANY, LTD., Hsin-Chu (TW)

(21) Appl. No.: 11/695,319

(22) Filed: Apr. 2, 2007

(51) Int. Cl. G03F 1/00

(52) U.S. Cl. 430/5

(57) ABSTRACT

The present disclosure provides a mask. The mask includes a transparent substrate, a main feature, and an assistant feature. The main feature includes attenuating material and is disposed on the substrate. The assistant feature includes a sub-resolution feature providing a phase shift. The assistant feature is spaced a distance from the main feature. The assistant feature includes a trench defined by the substrate. The present disclosure further provides a method of fabricating the mask.

### BACKGROUND

In semiconductor fabrication, photomasks are used to define patterns that will be printed on a semiconductor substrate, such as a semiconductor wafer, during the photolithography process. However, variations in the intended pattern may be induced by optical interference and other effects. To prevent these effects, scattering bars, also known as sub-resolution assist features, and for purposes of this disclosure, as assistant features, are included on the photomasks as an application of optical proximity correction (OPC). Assistant features may increase the resolution of the main feature with which they are associated. Conventional assistant features include narrow lines of material placed adjacent to a main feature. The conventional assistant features may be fabricated from attenuating material such as chrome or MoSi, and are disposed on and extend from the substrate of the photomask. As semiconductor dimensions decrease, the dimensions of the assistant features are also decreasing and quality control is becoming more difficult. Issues arising from the use of conventional assistant features include mask defects such as, the assistant features peeling off during photomask processing. The peeling may worsen with shrinking assistant features as the assistant feature will have limited contact area with the substrate. These mask defects may occur during processes such as, the photomask fabrication processes, photomask cleaning, and/or utilizing the photomask in the semiconductor fabrication process.

As such, an improved assistant feature reducing the possibility of mask defects is desired.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart illustrating an embodiment of a method of fabricating an assistant feature on a photomask.

FIG. 2a is a sectional view illustrating an embodiment of the method of FIG. 1.

FIG. 2b is a sectional view illustrating an embodiment of the method of FIG. 1.

FIG. 2c is a sectional view illustrating an embodiment of the method of FIG. 1.

FIG. 2d is a sectional view illustrating an embodiment of the method of FIG. 1.

FIG. 2e is a sectional view illustrating an embodiment of the method of FIG. 1.

FIG. 2f is a sectional view illustrating an embodiment of a photomask fabricated by the method of FIG. 1.

FIG. 2g is a top view illustrating an embodiment of the photomask of FIG. 2f.

FIG. 3a is a top view illustrating an alternative embodiment of the photomask of FIGS. 2f and 2g.

FIG. 3b is a top view illustrating an alternative embodiment of the photomask of FIGS. 2f and 2g.

FIG. 4 is a top view illustrating an embodiment of a photomask fabricated with the method of FIG. 1 and its aerial image.

### DETAILED DESCRIPTION

The present disclosure relates generally to the fabrication of semiconductor devices, and more particularly, to a sub-resolution assistant feature provided on a photomask. It is understood, however, that specific embodiments are provided as examples to teach the broader inventive concept, and one of ordinary skill in the art can easily apply the teaching of the present disclosure to other methods or apparatus. Also, it is understood that the methods and apparatus discussed in the present disclosure include some conventional structures and/or processes. Since these structures and processes are well known in the art, they will only be discussed in a general level of detail. Furthermore, reference numbers are repeated throughout the drawings for sake of convenience and example, and such repetition does not indicate any required combination of features or steps throughout the drawings.

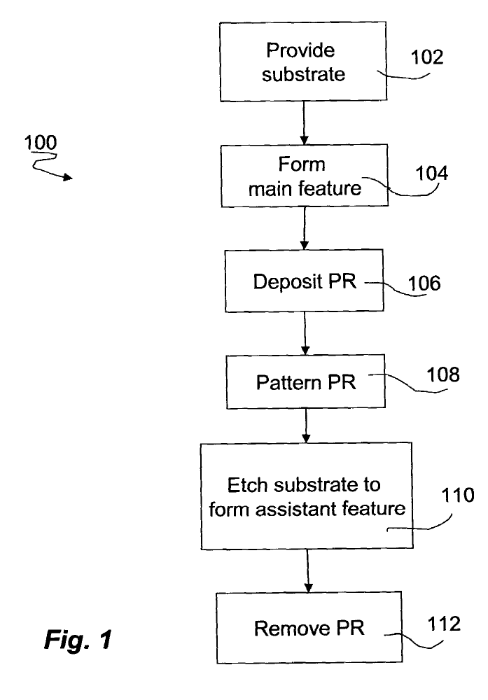

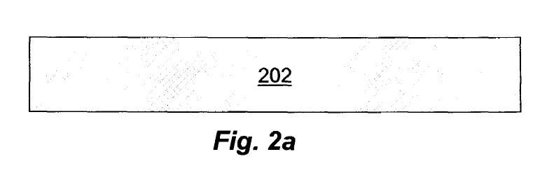

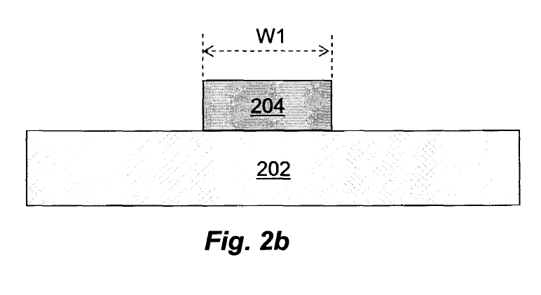

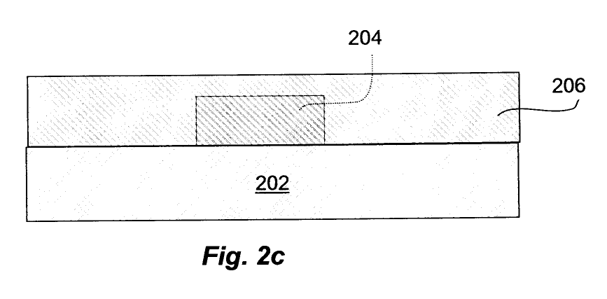

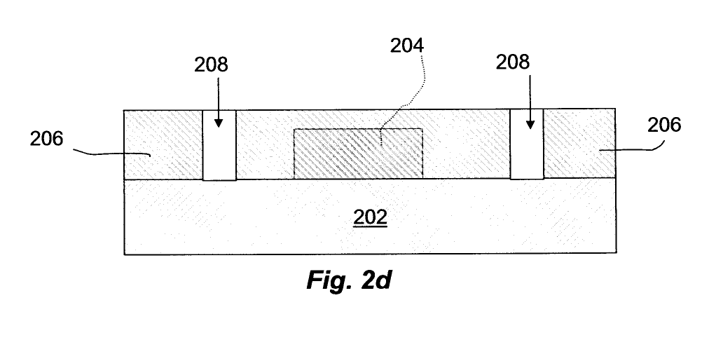

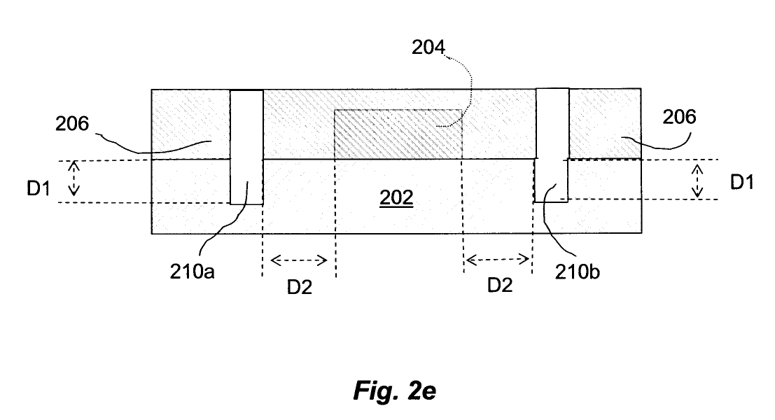

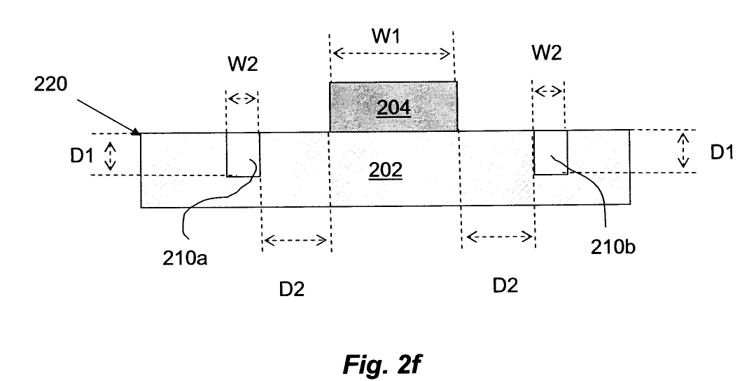

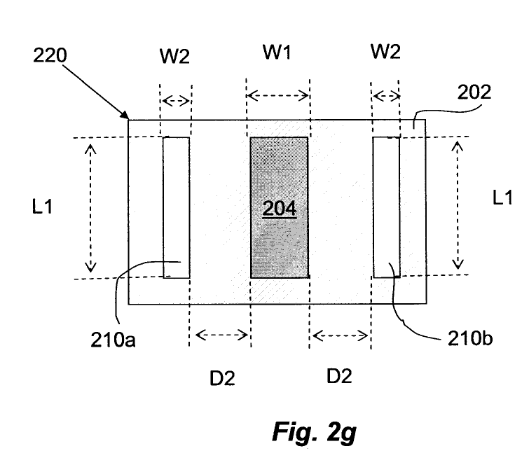

FIG. 1 illustrates an embodiment of a method 100 for the fabrication of an assistant feature on a photomask (mask, or reticle, collectively referred to as mask), and FIGS. 2a, 2b, 2c, 2d, 2e, 2f, and 2g show incremental modification of a semiconductor substrate 202 that correspond to the steps illustrated in FIG. 1.

The method 100 begins at step 102 where a substrate is provided. The substrate may be a transparent substrate such as fused silica (SiO₂), or quartz, relatively free of defects, calcium fluoride, or other suitable material. Referring to the example of FIG. 2a, the substrate 202 is provided.

The method 100 continues to step 104 where a main feature is formed. The main feature may be designed to form a portion of an integrated circuit pattern on a semiconductor substrate, such as a wafer. The main feature may be designed to form an integrated circuit feature such as a conductive line, a source and/or drain, a gate, and/or a doped region. Referring to the example of FIG. 2b, a main feature 204 is formed on the substrate 202. The main feature 204 has a width W1. The width W1 may be the critical dimension of the process. In an embodiment, the width W1 is approximately 90 nm for a mask used in a 90 nm semiconductor fabrication process. The main feature 204 may be formed of attenuating material. The attenuating material may include chrome or other materials such as, for example, Au, MoSi, CrN, Mo, Nb₂O₅, Ti, Ta, MoO₃, MoN, Cr₂O₃, TiN, ZrN, TiO₂, TaN, Ta₂O₅, NbN, Si₃N₄, ZrN, Al₂O₃N, Al₂O₃R, or a combination therefore. In an embodiment, the main feature 204 has a transmission of less than 10%. In an embodiment, the main feature 204 includes an attenuating material of chrome, and the transmission of the main feature 204 is approximately 0%.

The main feature 204 may be formed using conventional mask fabrication processes. A layer of attenuating material may be formed on the substrate 202. A layer of photoresist (PR) may be formed on the layer of attenuating material. The photoresist may be patterned. The patterning may be done using conventional photolithography processes. In an embodiment, the photolithography process includes soft baking, mask aligning, exposing, baking, developing the photoresist, and hard baking. In alternative embodiments, the lithography patterning used may include electron-beam writing, ion-beam writing, mask-less lithography, and/or molecular imprint. The patterned photoresist may create an opening exposing the attenuating material so that it may be removed from the substrate 202, leaving the attenuating material forming the main feature 204. In an embodiment, the attenuating material is removed by plasma etch or a wet etch. The remaining photoresist may be removed thereafter from the substrate 202 by wet stripping or plasma ashing.

The method 100 then proceeds to step 106 where a photoresist (PR) layer is formed on the substrate for lithography patterning. Referring to the example of FIG. 2c, the PR layer 206 is formed on the substrate 202. The PR layer 206 may be formed by depositing photoresist on the substrate 202. In an embodiment, the PR layer 206 is deposited by a spin-on coating method. The PR layer 206 may include chemical amplification resist (CAR). The PR layer 206 may enclose the main feature 204.

The method 100 proceeds to step 108 where the PR layer is patterned to form one or multiple openings creating the mask pattern on the substrate. Referring to the example of FIG. 2d, the PR layer 206 is patterned to include a plurality of openings 208 disposed a distance from the main feature 204. Patterning may be done using a conventional or future developed photolithography process known in the art. In an embodiment, the photolithography process includes soft baking, mask aligning, exposing, baking, developing the photoresist, and hard baking. In alternative embodiments, the lithography patterning may include electron-beam writing, ion-beam writing, mask-less lithography, and/or molecular imprint. The openings 208 expose the substrate 202 at a location designed for the formation of assistant features. In the illustrated embodiment, the openings 208 are positioned on two sides of the main feature 204 and are spaced a distance from the main feature 204. The openings formed may vary in number, geometry, dimension, and/or configuration as required to produce the assistant features as described below.

The method 100 proceeds to step 110 where assistant features are formed. The assistant features include sub-resolution features providing a phase shift and may be designed to optimize the imaging of the main feature during a photolithography process. A sub-resolution feature includes a feature having a dimension less than the resolution of the imaging system used with the mask. Referring to the example of FIGS. 2e, 2f, and 2g, assistant features 210a and 210b are formed. To form the assistant features 210a and 210b, the substrate 202 may be etched through the openings 208 of the PR layer 206; this may remove the substrate material and form trenches, or channels, defined by the substrate 202. In an embodiment, the etchant used to remove the substrate material includes hydrogen fluoride (HF). The assistant features 210a and 210b include the trenches etched to a depth D1 and spaced a distance D2 from the main feature 204. The depth D1 and the distance D2 are described in detail below. The method 100 proceeds to step 112 where the remaining photoresist of PR layer 206 is removed from the substrate 202 forming the mask 220. The photoresist may be removed by processes such as wet stripping or plasma ashing. In an embodiment, the method 100 continues with additional steps such as, the mask 220 completing mask fabrication processes known in the art, for example, cleaning. The use of assistant features 210a and 210b may eliminate the mask defect of the peeling off of assistant features during mask processing and/or use as the assistant features 210a and 210b are not reliant on adhesion force to the substrate to stay in place.

After completing the mask fabrication processes, the mask 220 may be a portion of a mask used to fabricate integrated circuit patterns on a semiconductor substrate. Alternatively, the mask 220 may be used to pattern other substrates such as, for example, a glass substrate used to form a thin film transistor liquid crystal display (TFT-LCD) substrate. A radiation beam may be used to form a feature from the mask 220 on the semiconductor substrate during a photolithography process. The radiation beam may be ultraviolet and/or can be extended to include other radiation beams such as ion beam, x-ray, extreme ultraviolet, deep ultraviolet, and other proper radiation energy.

Referring now in particular to FIGS. 2f and 2g, the mask 220, including the main feature 204 and the assistant features 210a and 210b, is illustrated in detail. The assistant features 210a and 210b may be scattering bars providing a phase shift relative to the substrate 202 in substantially unetched form. The substrate 202 in substantially unetched form includes that portion of the substrate 202 on which trenches have not been etched and no attenuating material is disposed. The substantially unetched portion of the substrate may include a planar substrate surface. The phase shift may be dependent upon the depth D1 of the trenches defined by the substrate 202 and included in the assistant features 210a and 210b. The depth D1 may be such that a radiation beam directed toward and through the assistant feature 210a and 210b has a phase shift relative to a radiation beam directed toward and through the substrate 202 in substantially unetched form. In an embodiment, the assistant features 210a or 210b provide a phase shift of approximately 180 degrees. In an embodiment, the assistant features 210a and 210b provide a phase shift between approximately 160 and 200 degrees. The transmission of the trenches of the assistant features 210a and 210b may be between approximately 80% and 100%. In the embodiment, the trenches may not be filled with material other than air from the surroundings.

The assistant features 210a and 210b are spaced a distance from the main feature 204, referenced as the distance D2. In an embodiment, D2 includes a distance such that an optical proximate effect is remedied. In an embodiment, the distance D2 includes distance such that an unintended ghost line is eliminated. In an embodiment, D2 is approximately 50 nanometers. In an embodiment, D2 is between approximately 10 and 320 nanometers. D2 may have a minimum distance that is dictated by process constraints of the mask fabrication process. The assistant features 210a and 210b include sub-resolution features. The trenches, included in the assistant features 210a and 210b, are defined by the substrate 202 have a width W2. In an embodiment, W2 is approximately 20 nanometers. In an embodiment, W2 is between approximately 5 and 160 nanometers. In an embodiment, W2 is no greater than approximately two-thirds of W1. L1, which is the length of the trenches of the assistant features 210a and 210b, may be multiple times W1. In the illustrated embodiment, the assistant features 210a and 210b are associated with the main feature 204 and are of similar dimensions. In alternative embodiments, the assistant feature 210a may have different dimensions than the assistant feature 210b. In an embodiment, the assistant feature 210a is spaced a different distance away from the main feature 204 than the assistant feature 210b.

In the illustrate embodiment, the assistant features 210a and 210b are rectangular-shaped trenches disposed on two sides of the main feature 204. The assistant feature however, may be designed in other geometries, dimensions, and/or configurations. In the illustrated embodiment, the assistant features 210a and 210b are associated with the main feature 204 and have similar geometries. In an embodiment, the assistant feature 210a is a different geometry than the assistant feature 210b. The number of assistant features associated with a main feature and the geometry of the assistant features associated with a single main feature may also vary. In an embodiment, the assistant feature is designed to include a plurality of trench segments, an annular trench, a trench of various other geometric shapes, or combinations thereof. In an embodiment, an assistant feature includes trenches combined to surround and enclose a main feature. In an embodiment, two or more main features are disposed adjacent to one another in the mask pattern allowing the main features to share assistant features; the assistant features being associated with a plurality of main features. The number, geometry, dimension, and configuration of assistant features may be determined by the patterning of the photoresist in step 108 described above.

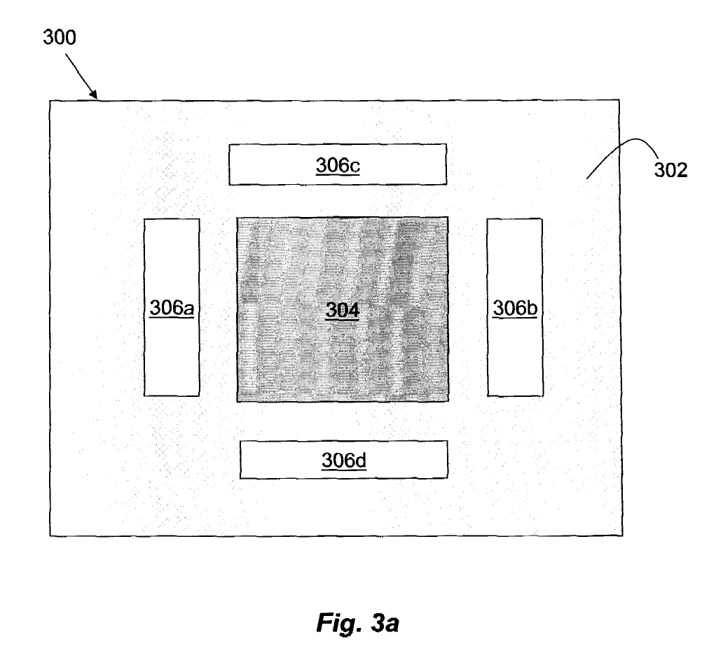

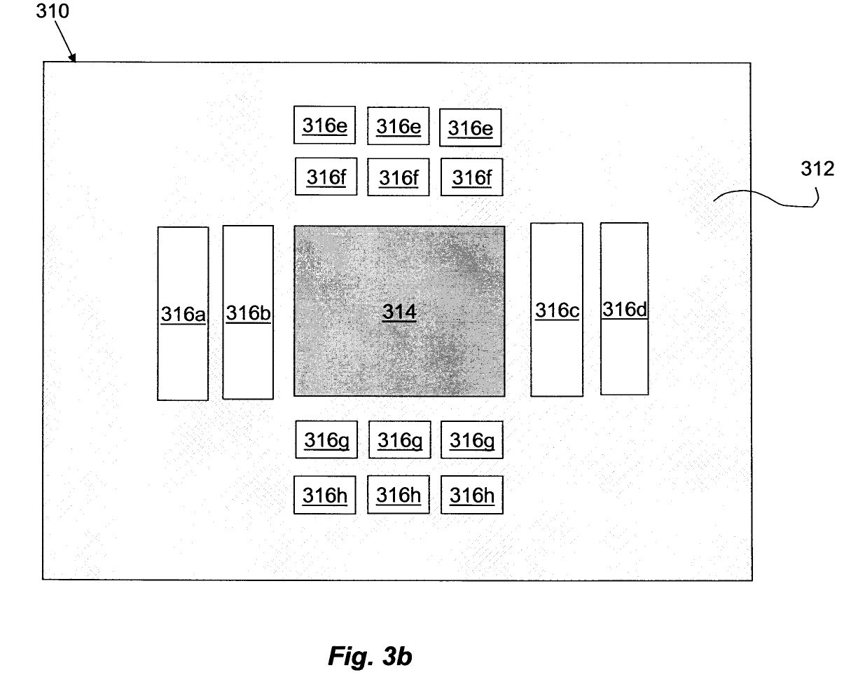

Referring now to FIG. 3a, an alternative embodiment of a configuration of a main feature and associated assistant features is illustrated. The illustration of FIG. 3a is not intended to be limiting. The mask 300 includes a substrate 302, a main feature 304, and a plurality of assistant features 306a, 306b, 306c, and 306d. The substrate 302 may include a transparent substrate and may be substantially similar to the substrate 202, described with reference to FIGS. 1 and 2a. The main feature 304 may include attenuating material and is disposed on the substrate 302; the main feature 304 may be substantially similar to the main feature 204, described with reference to FIGS. 1 and 2b. The plurality of assistant features 306a, 306b, 306c, and 306d are disposed around the main feature 304. The plurality of assistant features 306a, 306b, 306c, and 306d may include trenches defined by the substrate 302 and be substantially similar to the assistant features 210a and 210b, described with reference to FIGS. 1, 2e, 2f, and 2g. When a radiation beam is directed at and through the assistant features 306a, 306b, 306c, and 306d, the radiation beam may have a phase shift relative to a radiation beam directed at and through the substrate 302 in substantially unetched form. The phase shift may be substantially similar to that provided by the assistant features 210a and 210b, described above with reference to FIGS. 1, 2e, 2f, and 2g. The assistant features 306a, 306b, 306c, and 306d may be spaced a distance from the main feature 304. The assistant features 306a, 306b, 306c, and 306d may include sub-resolution features.

Referring now to FIG. 3b, an alternative embodiment of a configuration of a main feature and associated assistant features is illustrated. The illustration of FIG. 3b is not intended to be limiting. The mask 310 includes a substrate 312, a main feature 314, and a plurality of assistant features 316a, 316b, 316c, 316d, 316e, 316f, 316g, and 316h. The substrate 312 may include a transparent substrate and may be substantially similar to the substrate 202, described with reference to FIGS. 1 and 2a. The main feature 314 may include attenuating material and is disposed on the substrate 312; the main feature 314 may be substantially similar to the main feature 204, described with reference to FIGS. 1 and 2b. The plurality of assistant features 316a, 316b, 316c, 316d, 316e, 316f, 316g, and 316h are disposed around the main feature 314. The assistant features 316a, 316b, 316c, 316d, 316e, 316f, 316g, and 316h may include trenches defined by the substrate 312 and be substantially similar to the assistant features 210a and 210b, described above with reference to FIGS. 1, 2e, 2f, and 2g. When a radiation beam is directed at and through the assistant features 316a, 316b, 316c, 316d, 316e, 316f, 316g, and 316h, the radiation beam may have a phase shift relative to a radiation beam directed at and through the substrate 312 in substantially unetched form. The phase shift may be substantially similar to that provided by the assistant features 210a and 210b, described above with reference to FIGS. 1, 2e, 2f, and 2g. The assistant features 316a, 316b, 316c, 316d, 316e, 316f, 316g, and 316h may be spaced a distance from the main feature 314. The assistant features 316a, 316b, 316c, 316d, 316e, 316f, 316g, and 316h may include sub-resolution features. The assistant features 316e, 316f, 316g, and 316h illustrate a plurality of trench segments combined to form an assistant feature.

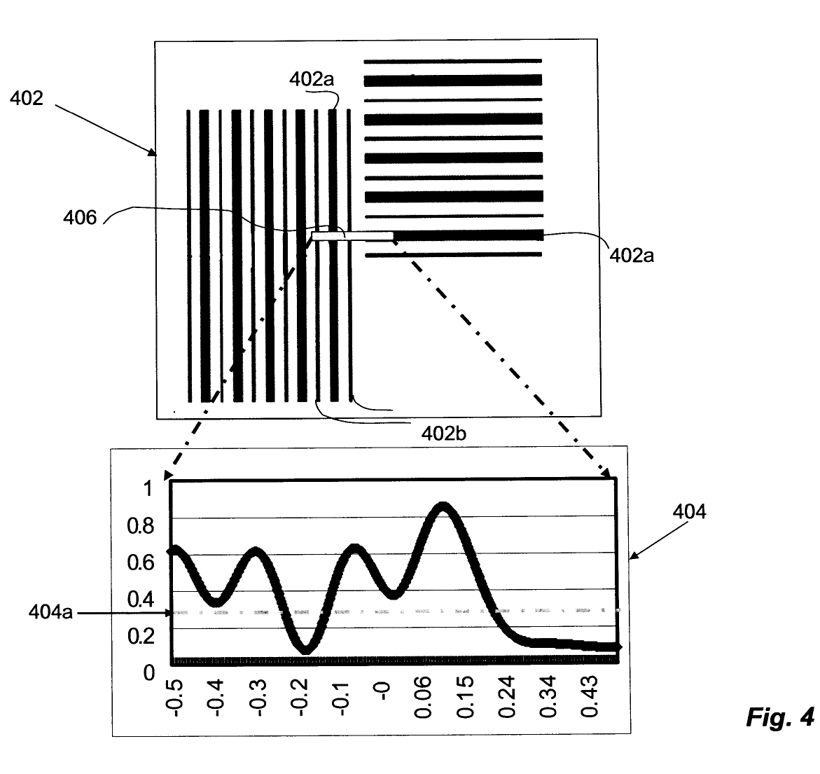

Referring now to FIG. 4, a mask 402 and an aerial image 404 corresponding to the mask 402 are illustrated. The mask 402 may be used in the photolithography process of semiconductor fabrication to define a portion of an integrated circuit pattern on a semiconductor substrate. The mask 402 includes main features represented as thick lines including a main features 402a and assistant features represented as thin lines including assistant features 402b. The mask 402 may be fabricated according to the method 100, described above with reference to FIG. 1. The main features 402a may include attenuating material. The assistant features 402b may include trenches defined by a transparent substrate. The integrated circuit pattern may be defined and formed by the main features 402a, the main features 402a being formed on the semiconductor substrate. The assistant features 402b however, may not be formed in the integrated circuit pattern on the semiconductor substrate. The assistant features 402b may include phase shift, sub-resolution features and may increase the resolution of the main feature. An aerial image includes a radiation intensity distribution at the wafer plane that would be produced by a radiation beam directed at and through a mask, taking into account the projection optics of the mask. An aerial image may therefore be utilized to determine what features on a mask may print on the wafer and may form integrated circuit features.

The aerial image 404 illustrates the radiation intensity distribution for a radiation beam directed and at through the mask 402, specifically the aerial image 404 captures a radiation beam intensity distribution of along a section 406 of the mask 402. The aerial image 404 includes an x-axis illustrating the location along the section 406 of the mask 402 in arbitrary units from −0.5 to 0.5; the y-axis includes the intensity. An intensity threshold 404a is illustrated on the y-axis at an intensity of approximately 0.3. When a radiation beam passes through the mask 402 and includes an intensity above the intensity threshold 404a, images may form on the photoresist (i.e. the photoresist is exposed) of the semiconductor substrate at that location. When a radiation beam passes through the mask and includes an intensity below the intensity threshold 404a, images may not form on the photoresist of the semiconductor substrate. The radiation intensity for a radiation beam directed at the main feature 402a is low, as illustrated by the curve at approximately −0.35 to −0.15 on the x-axis and approximately 0.20 on the x-axis. At these points, the intensity drops below the intensity threshold 404a. In an embodiment the photoresist is positive type resist and an image may not be printed on the photoresist (the photoresist not exposed) which allows the photoresist to remain on the wafer. This photoresist may allow for the formation of the main feature 402a in subsequent processing of the semiconductor substrate. The radiation intensity for a radiation beam directed at and through the assistant feature 402b, the assistant feature 402b including a trench defined by the mask 402 substrate, includes an intensity above the intensity threshold 404a as illustrated by the curve at approximately −0.4 on the x-axis and 0 on the x-axis. In an embodiment, the photoresist is positive type resist and an image may be printed on the photoresist at these locations which allows the photoresist to be removed and a feature not defined on the semiconductor substrate. Thus, an assistant feature, such as the assistant feature 402b, including a trench defined by a mask substrate may be used for OPC as it may not print a feature on the semiconductor wafer. In an embodiment, no ghost lines, or additional non-designed for features, around the main features, are produced.

Although only a few exemplary embodiments of this invention have been described in detail above, those skilled in the art will readily appreciate that many modifications are possible in the exemplary embodiments without material departing from the novel teachings and advantages of this disclosure.

Thus, the present disclosure provides a mask. In one embodiment, the mask includes a transparent substrate, a main feature, and an assistant feature. The main feature includes attenuating material and is disposed on the substrate. The assistant feature is spaced a distance from the main feature. The assistant feature includes a sub-resolution feature providing a phase shift. The assistant feature includes a trench defined by the substrate.

Also provided is a method of mask fabrication. A transparent substrate is provided. An attenuating feature disposed on the substrate is formed. A patterned photoresist layer is formed on the substrate. The substrate is etched using the patterned photoresist layer to form an assistant feature. The assistant feature is spaced a distance from the attenuating feature. The assistant feature includes a sub-resolution feature and provides a phase shift. The patterned photoresist layer is removed.

Also provided is a method of integrated circuit fabrication. The method includes providing a semiconductor substrate including a photoresist layer, providing a mask, and forming a main feature on the semiconductor substrate using the mask in a lithography process. The mask includes a transparent substrate, a main feature disposed on the substrate and a sub-resolution assistant feature located a distance from the main feature. The main feature includes an attenuating material. The assistant feature includes a trench defined by the transparent substrate.

What is claimed is:

1. A mask, comprising:
a transparent substrate;
a main feature comprising attenuating material and being disposed on the substrate; and
a first sub-resolution assistant feature spaced a first distance from the main feature, and wherein the first sub-resolution assistant feature includes a first trench defined by the substrate and providing a phase shift.

2. The mask of claim 1, wherein the substrate comprises a quartz material.

3. The mask of claim 1, wherein the attenuating material includes a chrome material.

4. The mask of claim 1, wherein the attenuating material includes a material selected from the group consisting of Au, MoSi, CrN, Mo, Nb₂O₅, Ti, Ta, MoO₃, MoN, Cr₂O₃, TiN, ZrN, TiO₂, TaN, Ta₂O₅, NbN, Si₃N₄, ZrN, Al₂O₃N, Al₂O₃R, and combinations thereof.

5. The mask of claim 1, wherein the first trench includes a depth providing a phase shift of a radiation beam relative to a substantially unetched portion of the substrate.

6. The mask of claim 5, wherein the phase shift is approximately 180 degrees.

7. The mask of claim 1, wherein a radiation beam directed at and through the first sub-resolution assistant feature includes a phase shift ranging between approximately 160 and 200 degrees relative to a radiation beam directed at and through a substantially planar portion of the substrate.

8. The mask of claim 1, wherein the first sub-resolution assistant feature has a transmission between approximately 80% and 100%.

9. The mask of claim 1, further comprising:
a second sub-resolution assistant feature disposed around the main feature and spaced a distance from the main feature, wherein the second sub-resolution assistant feature includes a second trench defined by the substrate.

10. The mask of claim 1, wherein the first distance is approximately 10 to 320 nanometers.

11. The mask of claim 1, wherein the first sub-resolution assistant feature is approximately 5 to 160 nanometers in width.

12. The mask of claim 1, wherein the first trench defined by the substrate includes a shape selected from the group consisting of a rectangle, an annular shape, a plurality of segments, and combinations thereof.

13. The mask of claim 1, wherein the main feature is designed to form an integrated circuit feature on a semiconductor substrate and the first sub-resolution assistant feature is designed such that the first sub-resolution assistant feature does not form an integrated circuit feature on a semiconductor substrate.

14. A method of mask fabrication, comprising:
providing a transparent substrate;
forming an attenuating feature disposed on the substrate;
forming a patterned photoresist layer on the substrate;
etching the substrate using the patterned photoresist layer to form a sub-resolution assistant feature spaced a first distance from the attenuating feature, wherein the sub-resolution assistant feature provides a phase shift; and
removing the patterned photoresist layer from the substrate.

15. The method of claim 14, wherein the forming the attenuating feature includes
forming a layer of attenuating material on the substrate;
forming a layer of photoresist on the layer of attenuating material;
patterning the layer of photoresist;
etching the layer of attenuating material using the patterned photoresist; and
removing the photoresist from the substrate.

16. The method of claim 14, wherein the etching the substrate comprises etching the substrate to a depth to provide a phase shift of a radiation beam directed at and through the etched substrate.

17. The method of claim 14, wherein the provided phase shift is between approximately 160 and 200 degrees relative to a phase shift provided by a substantially unetched portion of the substrate.

18. The method of claim 14, wherein the patterned photoresist layer includes openings spaced the first distance from the attenuating feature.

19. A method of integrated circuit fabrication, comprising:
providing a semiconductor substrate including a photoresist layer;
providing a mask including
a transparent substrate;
a main feature comprising attenuating material disposed on the transparent substrate; and
a sub-resolution assistant feature including a trench defined by the transparent substrate and located a distance from the main feature; and
forming the main feature on the semiconductor substrate using the mask in a lithography process.

20. The method of claim 20, wherein the lithography process includes a radiation beam, and wherein the radiation beam directed at the assistant feature has a phase shift of approximately 160 to 200 degrees relative to the radiation beam directed at the transparent substrate.
